(19) United States
(12) Patent Application Publication
(10) Pub. No.: US 2008/0176401 A1
(43) Pub. Date: Jul. 24, 2008

(54) METHOD FOR FORMING CONTACT HOLE

(75) Inventors: Pei-Yu Chou, Tainan County (TW); Jiunn-Hsiung Liao, Tainan County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/626,004

(22) Filed: Jan. 23, 2007

(51) Int. Cl. H01L 21/3065

(52) U.S. Cl. 438/694; 257/E21.218

(57) ABSTRACT

A method for forming a contact hole. The method comprises steps of performing a substrate having at least a dielectric layer formed thereon and then forming a patterned mask layer on the dielectric layer, wherein the patterned mask layer exposes a portion of the dielectric layer. The dielectric layer is patterned to form a contact hole by using the patterned mask layer as a mask, wherein an aspect ratio of the contact hole is larger than 4. The patterned mask layer is removed and a wet cleaning process is performed. A plasma treatment is performed on the substrate in a first tool system, wherein a gas source for the plasma treatment is a hydrogen-nitrogen-containing gas. A vacuum system of the first tool system is broken and then the substrate is transferred into a second tool system. An argon plasma treatment is performed on the substrate in the second tool system.

### BACKGROUND OF THE INVENTION

1. Field of Invention

The present invention relates to a semiconductor process. More particularly, the present invention relates to a method for forming a contact hole with an aspect ratio larger than 4.

2. Description of Related Art

In semiconductor processes, a conductive line is formed between the two conductive layers as an electrical connection. The conductive line is called a via plug. If the conductive line is formed between a metal layer and a metal oxide semiconductor (MOS) as an electrical connection, the conductive line is called a contact plug. With the increasing integration in integrated circuits, the aspect ratio of the contact hole becomes larger and larger so that the polymer residue generated by etching the contact hole is easily remains on the sidewalls and the bottom of the contact hole.

Conventionally, after the contact hole is formed and the patterned photoresist layer is removed, a wet cleaning process is performed to remove the possible polymer residue and the etching byproduct on the sidewalls and the bottom of the contact hole. However, as the integration of the circuit is increased and the aspect ratio of the contact hole is increased, it is hard to remove the polymer residue and the etching byproduct away from such a narrow contact hole. Therefore, the polymer residue and the etching byproduct remains on sidewalls and bottom of the contact hole leads to unstable electrical performance of the device and the reliability of the device is decreased.

### SUMMARY OF THE INVENTION

Accordingly, at least one objective of the present invention is to provide a method for forming a contact hole capable of removing the polymer residue and etching byproduct away from the contact hole having an aspect ratio larger than 4.

To achieve these and other advantages and in accordance with the purpose of the invention, as embodied and broadly described herein, the invention provides a method for forming a contact hole. The method comprises steps of performing a substrate having at least a dielectric layer formed thereon and then forming a patterned mask layer on the dielectric layer, wherein the patterned mask layer exposes a portion of the dielectric layer. The dielectric layer is patterned to form a contact hole by using the patterned mask layer as a mask, wherein an aspect ratio of the contact hole is larger than 4. The patterned mask layer is removed and a wet cleaning process is performed. A plasma treatment is performed on the substrate in a first tool system, wherein a gas source for the plasma treatment is a hydrogen-nitrogen-containing gas. A vacuum system of the first tool system is broken and then the substrate is transferred into a second tool system. An argon plasma treatment is performed on the substrate in the second tool system.

According to one embodiment of the present invention, a contact etching stop layer is disposed between the dielectric layer and the substrate. After the step for removing the patterned mask layer, the method further comprises a step of removing a portion of the contact etching stop layer exposed by the contact hole. Furthermore, a metal silicide layer is disposed underneath the contact etching stop layer the contact hole exposes a portion of the metal silicide layer.

According to one embodiment of the present invention, the patterned mask layer is made of photoresist. The method for removing the patterned mask layer made of photoresist includes an oxygen plasma etching.

According to one embodiment of the present invention, after the step for performing the argon plasma treatment, the method further comprises a step of forming a barrier layer over the substrate. The step of forming a barrier layer is performed by the second tool system.

The present invention also provides a method for forming a contact hole. The method comprises steps of providing a substrate having at least a dielectric layer formed thereon and then forming a patterned photoresist layer over the substrate. A contact hole is formed in the dielectric layer by using the patterned photoresist layer as a mask, wherein an aspect ratio of the contact hole is larger than 4. The patterned photoresist layer is removed and a wet cleaning process is performed. A plasma treatment with a hydrogen-nitrogen-containing gas as a gas source is performed on the substrate in a tool system and a barrier layer is formed over the substrate in the tool system.

According to one embodiment of the present invention, before the barrier layer is formed and after the plasma treatment is performed, the method further comprises a step of performing an argon plasma treatment on the substrate in the tool system.

According to one embodiment of the present invention, a contact etching stop layer is disposed between the dielectric layer and the substrate. After the step for removing the patterned photoresist layer, the method further comprises a step of removing a portion of the contact etching stop layer exposed by the contact hole. Moreover, a metal silicide layer is disposed underneath the contact etching stop layer the contact hole exposes a portion of the metal silicide layer.

According to one embodiment of the present invention, the method for removing the patterned photoresist layer includes an oxygen plasma etching.

In the present invention, since the plasma treatment with the use of the hydrogen-nitrogen-containing gas as a gas source is performed after the contact hole is formed in the dielectric layer and the wet cleaning process is performed, the polymer residue and the etching byproduct which are hardly removed due to the high aspect ratio of the contact hole, can be completely removed from the contact hole.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1C are cross-sectional views showing a method for forming a contact hole according to one embodiment of the present invention.

FIG. 2 is a flow chart showing a method for forming a contact hole according to one embodiment of the present invention.

FIG. 3 is a flow chart showing a method for forming a contact hole according to the other embodiment of the present invention.

### DESCRIPTION OF EMBODIMENTS

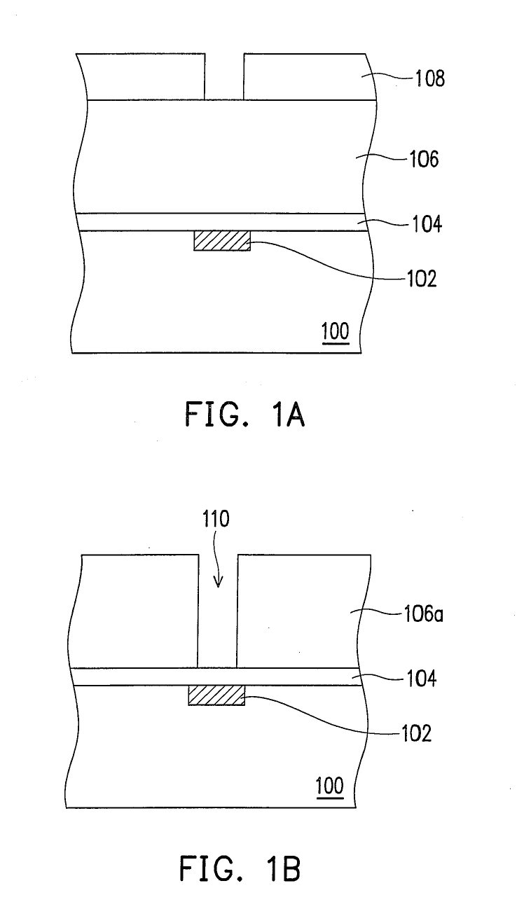

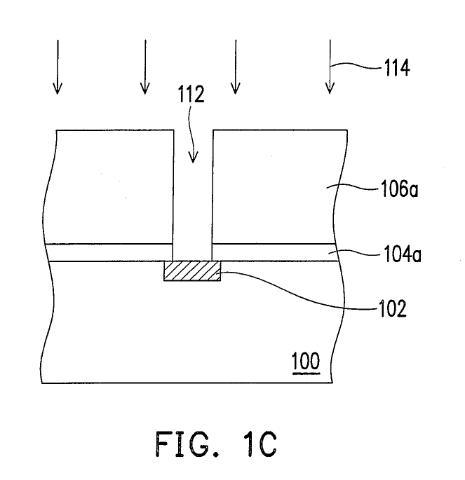

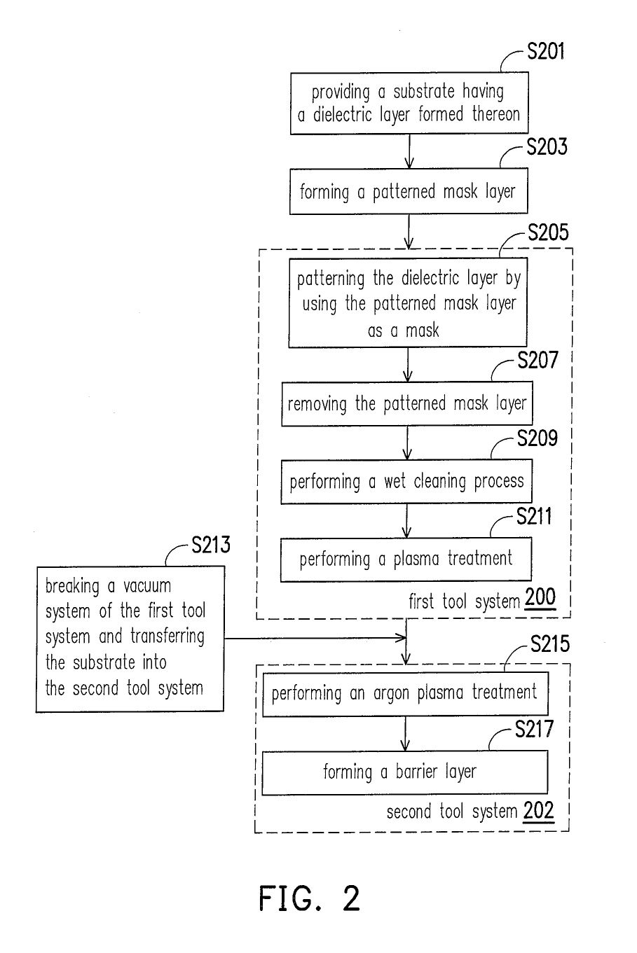

FIGS. 1A through 1C are cross-sectional views slowing a method for forming a contact hole according to one embodiment of the present invention. FIG. 2 is a flow chart showing a method for forming a contact hole according to one embodiment of the present invention. As shown in FIG. 1A and FIG. 2, in the step S201, a substrate 100 is provided. The substrate 100 has at least one dielectric layer 106 formed thereon. Furthermore, a contact etching stop layer 104 is disposed between the dielectric layer 106 and the substrate 100. Also, below the contact etching stop layer 104, there is a conductive layer 102. The conductive layer 102 can be, for example, made of metal silicide such as nickel silicide or cobalt silicide. Then, a patterned mask layer 108 is formed over the substrate 100 (step S203). The patterned mask layer 108 can be, for example, made of photoresist.

As shown in FIG. 1B together with FIG. 2, the dielectric layer 106 is patterned to form a contact hole 112 (shown in FIG. 1C) by using the patterned mask layer 108 as a mask. The contact hole 112 has an aspect ratio larger than 4. The method for forming the contact hole 112 comprises steps of performing an etching process to remove a portion of the dielectric layer 106 exposed by the patterned mask layer 108 (step S205) and then removing the patterned mask layer 108 (step S207). Meanwhile, the dielectric layer 106 is transformed into a dielectric layer 106a with a hole 110 therein and the hole 110 exposes a portion of the contact etching stop layer 104. Thereafter, as shown in FIG. 1C, a portion of the contact etching stop layer 104 is removed to expose the conductive layer 102 underneath so that the contact hole 112 is formed. When the patterned mask layer is made of photoresist, the method for removing the patterned mask layer can be, for example, a dry etching process such as an oxygen plasma etching process.

Then, as shown in FIG. 1C and FIG. 2, a wet cleaning process (step S209) followed by a plasma treatment 114 (step S211) is performed. The plasma treatment is performed with the use of a hydrogen-nitrogen-containing gas as a gas source. Notably, because of the plasma treatment, the polymer residue and the etching byproduct, which are hard to be removed due to the high aspect ratio of the contact hole, can be completely removed away from the contact hole 112 even though the aspect ratio of the contact hole 112 is larger than 4.

In one embodiment, as shown in FIG. 2, the plasma treatment 114 is performed in a first tool system 200 in which the dielectric layer 106 and the contact etching stop layer 104 are patterned and the patterned mask layer 108 is removed. The first tool system can be, for example, an etching tool system. After the plasma treatment is performed, a vacuum system of the first tool system 200 is broken and the substrate 100 is transferred into a second tool system 202 (step S213). The second tool system 202 can be, for example, a deposition tool system. Still in FIG. 2, an argon plasma treatment is performed on the substrate 100 in the second tool system 202. The argon plasma treatment is served to be a pre-cleaning process for the later performed processes. Thereafter, a barrier layer (not shown in FIG. 1C) is formed over the substrate 100 (step S217) in the second tool system 202.

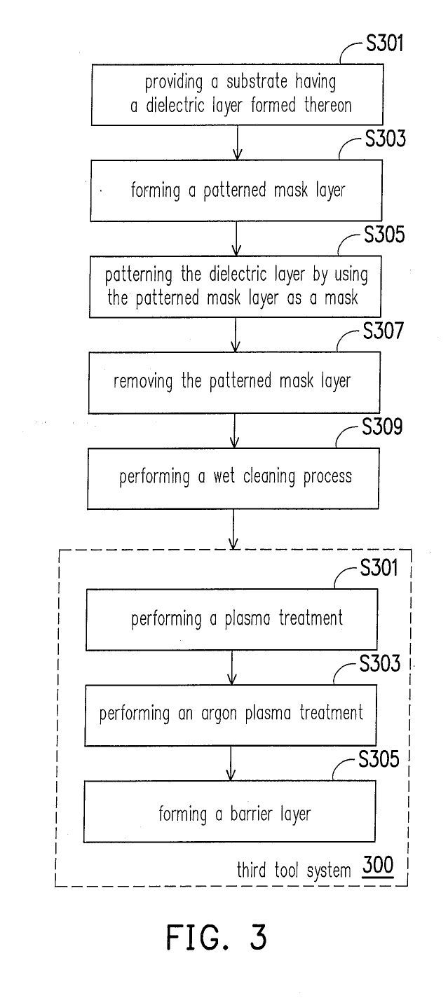

Alternatively, in the other embodiment, as shown in FIG. 3, by following the steps S301, S303, S305, S307 and S309, a contact hole such as 112 in FIG. 1C is formed in the dielectric layer 106a. The steps S301, S303, S305, S307 and S309 are as same as the steps S201, S203, S205, S207, S209 so that detail of the steps S301, S303, S305, S307 and S309 are not described herein. Then, a plasma treatment with the use of the hydrogen-nitrogen-containing gas as a gas source is performed (step S311). Moreover, an argon plasma treatment is performed (step S313) and a barrier layer is formed over the substrate 100 (step S315). It should be noticed that, in this embodiment, the steps S311, S313 and S315 are performed in the same tool system, the third tool system 300. That is, the third tool system 300 is an integrated tool system comprising functionalities of plasma bombardment and deposition. Thus, the plasma treatment for removing the polymer residue and the etching byproduct in the contact hole 112 and the formation of the barrier layer can be performed in the same tool system.

In the present invention, the plasma treatment with the use of the hydrogen-nitrogen-containing gas as a gas source is performed after the contact hole is formed in the dielectric layer and the wet cleaning process is performed. Therefore, the polymer residue and the etching byproduct which are hardly removed due to the high aspect ratio of the contact hole, can be completely removed from the contact hole. Furthermore, according to the types of the tool systems, the plasma treatment can be performed either in an etching tool system or in a deposition tool system integrated with a plasma bombardment chamber.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method for forming a contact hole, comprising:
performing a substrate having at least a dielectric layer formed thereon;
forming a patterned mask layer on the dielectric layer, wherein the patterned mask layer exposes a portion of the dielectric layer;
patterning the dielectric layer to form a contact hole by using the patterned mask layer as a mask, wherein an aspect ratio of the contact hole is larger than 4;
removing the patterned mask layer;
performing a wet cleaning process;
performing a plasma treatment on the substrate in a first tool system, wherein a gas source for the plasma treatment is a hydrogen-nitrogen-containing gas;
breaking a vacuum system of the first tool system;
transferring the substrate into a second tool system;
performing an argon plasma treatment on the substrate in the second tool system.

2. The method of claim 1, wherein a contact etching stop layer is disposed between the dielectric layer and the substrate.

3. The method of claim 2, after the step for removing the patterned mask layer, further comprising steps of:
removing a portion of the contact etching stop layer exposed by the contact hole.

4. The method of claim 2, wherein a metal silicide layer is disposed underneath the contact etching stop layer and the contact hole exposes a portion of the metal silicide layer.

5. The method of claim 1, wherein the patterned mask layer is made of photoresist.

6. The method of claim 5, wherein the method for removing the patterned mask layer includes an oxygen plasma etching.

7. The method of claim 1, after the step for performing the argon plasma treatment, further comprising steps of:
forming a barrier layer over the substrate.

8. The method of claim 7, wherein the step of forming a barrier layer is performed by the second tool system.

9. A method for forming a contact hole, comprising:
providing a substrate having at least a dielectric layer formed thereon;
forming a patterned photoresist layer over the substrate;
forming a contact hole in the dielectric layer by using the patterned photoresist layer as a mask, wherein an aspect ratio of the contact hole is larger than 4;
removing the patterned photoresist layer;
performing a wet cleaning process;
performing a plasma treatment with a hydrogen-nitrogen-containing gas as a gas source on the substrate in a tool system; and
forming a barrier layer over the substrate in the tool system.

10. The method of claim 9, wherein before the barrier layer is formed and after the plasma treatment is performed, further comprising a step of performing an argon plasma treatment on the substrate in the tool system.

11. The method of claim 9, wherein a contact etching stop layer is disposed between the dielectric layer and the substrate.

12. The method of claim 11, after the step for removing the patterned photoresist layer, further comprising steps of:
removing a portion of the contact etching stop layer exposed by the contact hole.

13. The method of claim 11, wherein a metal silicide layer is disposed underneath the contact etching stop layer the contact hole exposes a portion of the metal silicide layer.

14. The method of claim 9, wherein the method for removing the patterned photoresist layer includes an oxygen plasma etching.
